(19) United States
(12) Patent Application Publication
(10) Pub. No.: US 2021/0125843 A1
(43) Pub. Date: Apr. 29, 2021

(54) AIR CONTROL CABINET MODULE AND CLEAN ROOM SYSTEM HAVING THE SAME

(71) Applicant: XIA TAI XIN SEMICONDUCTOR (QING DAO) LTD., Qingdao (CN)

(72) Inventors: SUNG-UK KIM, Singapore (SG); BUM-HWAN JEON, Singapore (SG); JIYONG YOO, Singapore (SG); BYUNG-IN KWON, Singapore (SG); HYUN-SUK YANG, Singapore (SG); SOO-HYOUNG KIM, Singapore (SG)

(21) Appl. No.: 16/663,280

(22) Filed: Oct. 24, 2019

(51) Int. Cl. H01L 21/67; F24F 3/16

(52) U.S. Cl. CPC H01L 21/67017; F24F 3/161

(57) ABSTRACT

The present disclosure provides an air control cabinet (ACC) module for a clean room system. The clean room system has a clean fab and a clean sub-fab. The clean fab of the clean room system is configured to be disposed with at least one wafer processing apparatus. The ACC module includes an ACC inlet tube, a main cabinet, and an ACC pipeline. The ACC inlet tube is configured to supply air from the clean fab of the clean room system to the ACC module. The main cabinet is connected to the ACC inlet tube and configured to generate clean air from the air supplied from the ACC inlet tube. The ACC pipeline is connected to the main cabinet and configured to supply the clean air generated by the main cabinet to the wafer processing apparatus in the clean fab of the clean room system.

### FIELD

The present disclosure generally relates to an air control cabinet module and a clean room system having the same. More specifically, the present disclosure relates to an air control cabinet module having an inlet tube to draw air from a clean fab of a clean room system.

### BACKGROUND

Integrated circuits are generally made by photolithographic processes (or exposure processes) that use reticles (or photomasks) and an associated light source to project a circuit image on the surface of a semiconductor wafer. The photolithography process entails coating the wafer with a layer of photoresist, exposing the layer of photoresist and then developing the exposed photoresist. During the process of exposing the layer of photoresist (e.g., an exposure process), the wafer coated with a layer of photoresist is loaded to an exposure apparatus (e.g., a scanner or a stepper) to be exposed with a pattern of a reticle. Particle contamination to the exposure apparatus and the reticle may cause the photolithographic pattern transmitted on the wafer to change, distort, or alter from its intended design, ultimately impacting the quality of the semiconductor device manufactured.

In order to reduce particle contamination, the exposure process must be performed in a clean room system. The clean room system includes a clean fab and a clean sub-fab. The clean fab of the clean room system is used to accommodate wafer processing apparatus (such as the exposure apparatus) that has a high requirement for particle concentration. The clean sub-fab of the clean room system is used to accommodate auxiliary equipments that do not directly process the wafer (such as power supply equipment, pumps, or ventilation control device). Such auxiliary equipments may cause vibration that results in an increased particle concentration in the atmosphere. Therefore, those auxiliary equipments are disposed in a separate space from the wafer processing apparatus. The air in the clean room system is continuously circulated between the clean sub-fab and clean fab. Specifically, the air in the clean sub-fab is filtered and then supplied to the clean fab, and the air in the clean fab flows to the clean sub-fab through vent holes of the clean room system.

For the exposure apparatus that has strict requirements for particle concentration, an air control cabinet supplies processed air that has a particle concentration lower than a predetermined level to an inlet port of the exposure apparatus. Therefore, a particle concentration requirement of the exposure apparatus can be ensured. However, the air control cabinet is usually disposed in the clean sub-fab, and the air drawn into the air control cabinet has a high particle concentration. There remains a need in the art to improve the cleanliness of the air supplied to the exposure apparatus.

### SUMMARY

The present disclosure is directed to provide an air control cabinet (ACC) module to improve air quality supplied to a wafer processing apparatus in a clean room system.

An implementation of the present disclosure provides an air control cabinet (ACC) module for a clean room system. The clean room system has a clean fab and a clean sub-fab. The clean fab of the clean room system is configured to be disposed with at least one wafer processing apparatus. The ACC module includes an ACC inlet tube, a main cabinet, and an ACC pipeline. The ACC inlet tube is configured to supply air from the clean fab of the clean room system to the ACC module. The main cabinet is connected to the ACC inlet tube and configured to generate clean air from the air supplied from the ACC inlet tube. The ACC pipeline is connected to the main cabinet and configured to supply the clean air generated by the main cabinet to the wafer processing apparatus in the clean fab of the clean room system.

Another implementation of the present disclosure provides a clean room system for processing semiconductor wafers. The clean room system includes a main body, a floor, and an air control cabinet (ACC) module. The main body of the clean room system has an inner space. The floor of the clean room system is disposed in the inner space of the main body. The inner space of the main body is divided into a clean fab and a clean sub-fab by the floor. The clean fab is configured to be disposed with at least one wafer processing apparatus. The ACC module includes an ACC inlet tube, a main cabinet, and an ACC pipeline. The ACC inlet tube is configured to supply air from the clean fab of the clean room system to the ACC module. The main cabinet is connected to the ACC inlet tube and configured to generate clean air from the air supplied from the ACC inlet tube. The ACC pipeline is connected to the main cabinet and configured to supply the clean air generated by the main cabinet to the wafer processing apparatus in the clean fab of the clean room system.

Another implementation of the present disclosure provides a method of improving air quality of a wafer processing apparatus in a clean room system. The clean room system has a clean fab and a clean sub-fab. The wafer processing apparatus is disposed in the clean fab of the clean room system. In a first action of the method, an air control cabinet (ACC) module is provided to the clean room system. The ACC module includes an ACC inlet tube, a main cabinet, and an ACC pipeline. In a second action of the method, the ACC pipeline of the ACC module is connected to an inlet port of the wafer processing apparatus. In a third action of the method, the ACC inlet tube of the ACC module supplies air from the clean fab of the clean room system to the main cabinet of the ACC module. In a fourth action of the method, the main cabinet of the ACC module generates clean air from the air supplied from the ACC inlet tube. In a fifth action of the method, the clean air generated by the main cabinet is supplied to the wafer processing apparatus through the ACC pipeline of the ACC module.

As described above, the ACC module in accordance with implementations of the present disclosure has an ACC inlet tube that can draw air from the clean fab of the clean room system. The air in the clean fab is filtered by the clean fab filter, and has a higher air quality (or a lower particle concentration) than the air in the clean sub-fab. Therefore, the ACC module in accordance with implementations of the present disclosure ensures the cleanliness of the air supplied into the wafer processing apparatus. Also, the service life of filters in the ACC module is prolonged by providing air with lower particle concentrations.

### BRIEF DESCRIPTION OF THE DRAWINGS

Implementations of the present technology will now be described, by way of example only, with reference to the attached figures.

FIG. 1 is a schematic diagram of a clean room system according to an implementation of the present disclosure.

FIG. 2 is a schematic diagram of a clean room system according to another implementation of the present disclosure.

FIG. 3 is a schematic diagram of an exposure apparatus disposed in the clean room in FIG. 2.

FIGS. 4A and 4B are schematic diagrams of an air control cabinet (ACC) module of the clean room system in FIG. 2.

FIG. 5 is a flowchart of a method of improving air quality of a wafer processing apparatus according to an implementation of the present disclosure.

### DETAILED DESCRIPTION

The present disclosure will now be described more fully hereinafter with reference to the accompanying drawings, in which example implementations of the disclosure are shown. This disclosure may, however, be embodied in many different forms and should not be construed as limited to the example implementations set forth herein. Rather, these example implementations are provided so that this disclosure will be thorough and complete, and will fully convey the scope of the disclosure to those skilled in the art. Like reference numerals refer to like elements throughout.

The terminology used herein is for the purpose of describing particular example implementations only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, actions, operations, elements, and/or components, but do not preclude the presence or addition of one or more other features, regions, integers, actions, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

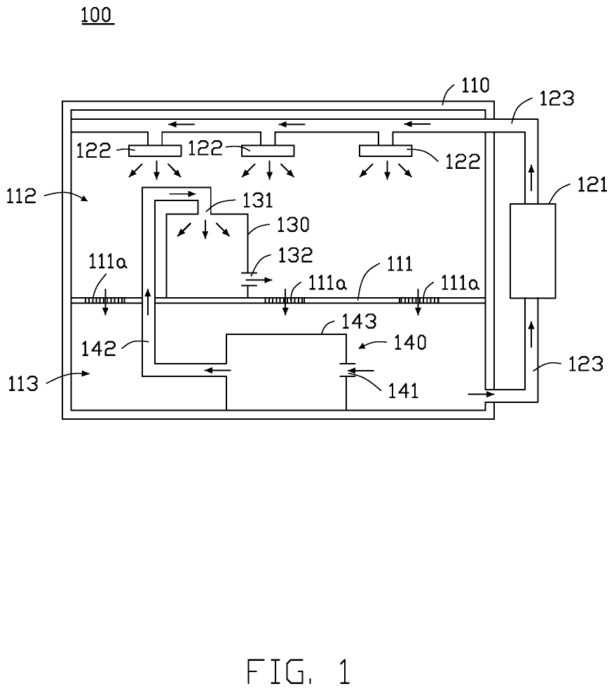

The description will be made as to the example implementations of the present disclosure in conjunction with the accompanying drawings in FIGS. 1 through 5. Reference will be made to the drawing figures to describe the present disclosure in detail, wherein depicted elements are not necessarily shown to scale and wherein like or similar elements are designated by same or similar reference numeral through the several views and same or similar terminology.

The present disclosure will be further described hereafter in combination with the accompanying figures.

Referring to FIG. 1, a schematic diagram of a clean room system 100 according to an implementation of the present disclosure is illustrated. As shown in FIG. 1, the clean room system 100 includes a main body 110 having an inner space, a floor 111 disposed in the inner space of the main body 110, and an air control cabinet (ACC) module 140. The inner space of the main body 110 is divided into a clean fab 112 and a clean sub-fab 113 by the floor 111. The clean fab 112 is configured to be disposed with at least one wafer processing apparatus 130 (e.g., an etching apparatus, a spin-coating apparatus, a chemical mechanical polishing apparatus, a cleaning apparatus, an exposure apparatus, etc.). The clean sub-fab 113 is configured to be disposed with at least one auxiliary equipments (e.g., power supply equipments, ventilation control equipments, pumps, etc.). The auxiliary equipments may provide powers, ventilation, or other functions to the wafer processing apparatus 130, and do not directly process the wafers. Usually, the wafer processing apparatus 130 requires a high standard for air cleanliness (or a low particle concentration in the air) to prevent wafer defect. The auxiliary equipments often generate vibration which causes an increase in particle concentration in the air. Therefore, the wafer processing apparatus 130 and the auxiliary equipments are respectively disposed in separate spaces of the clean room system 100 (e.g., the clean fab 112 and the clean sub-fab 113) to ensure air cleanliness of the wafer processing apparatus 130.

The air in the clean room system 100 circulates between the clean fab 112 and the clean sub-fab 113. The clean room system 100 further includes a clean room pipeline 123, a main filter 121, and at least one clean fab filter 122. The clean room pipeline 123 is coupled to the clean fab 112 and the clean sub-fab 113, and configured to supply filtered air from the clean sub-fab 113 to the clean fab 112. The main filter 121 is coupled to the clean room pipeline 123 and configured to filter the air supplied from the clean sub-fab 113. The at least one clean fab filter 122 is connected to the clean room pipeline 123. The clean fab filter 122 is disposed in the clean fab 112, and configured to filter the air from the clean sub-fab 113 before supplying the filtered air to the clean fab 112. The main filter 121 and the clean fab filter 122 may be high efficiency particulate air (HEPA) filters. The HEPA filters can remove at least 99.95% of particles having a diameter greater than or equal to 0.3 micrometers from the air that passes therethrough. The HEPA filters may each include a mat of randomly arranged fibers. The fibers are typically composed of fiberglass and have diameters between 0.5 and 2.0 micrometers. The floor 111 of the clean room system 100 includes at least one vent area 111a for air communication between the clean fab 112 and the clean sub-fab 113. Specifically, the air flows from the clean fab 112 to the clean sub-fab 113 through the vent area 111a. The vent area 111a has a plurality of vent holes for allowing air-communication between the clean fab 112 and the clean sub-fab 113. Therefore, the air in the clean sub-fab 113 is pumped into the clean room pipeline 123, filtered by the main filter 121, filtered by the clean fab filter 122, and supplied to the clean fab 112. The air in the clean fab 112 blows the particles away from the clean fab 112 and flows into the clean sub-fab 113 through the vent holes in the vent area 111a. Accordingly, the air is continuously filtered and circulated in the clean fab 112 and the clean sub-fab 113 of the clean room system 100. For the wafer processing apparatus 130 disposed in the clean fab 112, the ACC module 140 supplies clean air to an inlet port 131 of the wafer processing apparatus 130. The ACC module 140 draws air from the clean sub-fab 113, filters the particles in the air, and adjusts temperature and humidity of the filtered air to meet the air quality requirement of the wafer processing apparatus 130. As shown in FIG. 1, the air supplied from the ACC module 140 blows the particles away from the wafer processing apparatus 130, and then flows into the clean fab 112 through a vent port 132 of the wafer processing apparatus 130. Accordingly, the particle concentration in the wafer processing apparatus 130 can be maintained at a low level.

The ACC module 140 includes an ACC inlet port 141, a main cabinet 143, and an ACC pipeline 142. The ACC inlet port 141 is configured to supply air from the clean sub-fab 113 of the clean room system 100 to the ACC module 140. The main cabinet 143 is configured to generate clean air from the air supplied from the clean sub-fab 113 via the ACC inlet port 141. The main cabinet 143 may include a fan, a chemical filter, and a moisture control unit. The fan of the main cabinet 143 is configured to draw the air from the clean sub-fab 113 into the main cabinet 143 through the ACC inlet port 141. The chemical filter of the main cabinet 143 is configured to remove chemical materials and/or particles in the air drawn by the fan of the main cabinet 143. The moisture control unit is configured to control a moisture and a temperature of the air supplied from the ACC inlet port 141. The ACC pipeline 142 is connected to the main cabinet 143 and configured to supply the clean air generated by the main cabinet 143 to the wafer processing apparatus 130 in the clean fab 112 of the clean room system 100. The ACC pipeline 142 has two ends. One end of the ACC pipeline 142 is connected to the main cabinet 143. The other end of the ACC pipeline 142 is connected to the inlet port 131 of the wafer processing apparatus 130. The air supplied from the ACC pipeline 142 of the ACC module 140 blows the particles away from the wafer processing apparatus 130, and then flows into the clean fab 112 through the vent port 132 of the wafer processing apparatus 130. Therefore, the ACC module 140 ensures the air quality (e.g., particle and chemical material concentration, moisture, temperature, etc.) in the wafer processing apparatus 130.

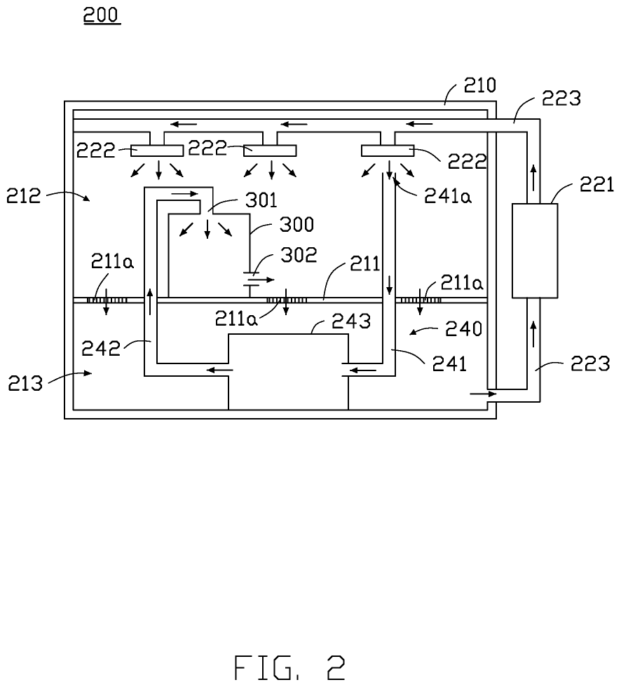

Referring to FIG. 2, a schematic diagram of a clean room system 200 according to another implementation of the present disclosure is illustrated. As shown in FIG. 2, the clean room system 200 includes a main body 210 having an inner space, a floor 211 disposed in the inner space of the main body 210, and an air control cabinet (ACC) module 240. The inner space of the main body 210 is divided into a clean fab 212 and a clean sub-fab 213 by the floor 211. The clean fab 212 is configured to be disposed with at least one wafer processing apparatus. The clean sub-fab 213 is configured to be disposed with at least one auxiliary equipments (e.g., power supply equipments, ventilation control equipments, pumps, etc.). The auxiliary equipments may provide powers, ventilation, or other functions to the wafer processing apparatus and do not directly process the wafers. Usually, the wafer processing apparatus requires a high standard for air cleanliness (or a low particle concentration in the air) to prevent wafer defect. The auxiliary equipments often generate vibration which causes an increase in particle concentration in the air. Therefore, the wafer processing apparatus and the auxiliary equipments are respectively disposed in separate spaces of the clean room system 200 (e.g., the clean fab 212 and the clean sub-fab 213) to ensure air cleanliness of the wafer processing apparatus. The wafer processing apparatus may be an exposure apparatus 300 for transferring a pattern onto a semiconductor wafer, as shown in FIG. 2.

The air in the clean room system 200 circulates between the clean fab 212 and the clean sub-fab 213. The clean room system 200 further includes a clean room pipeline 223, a main filter 221, and at least one clean fab filter 222. The clean room pipeline 223 is coupled to the clean fab 212 and the clean sub-fab 213, and configured to supply filtered air from the clean sub-fab 213 to the clean fab 212. The main filter 221 is coupled to the clean room pipeline 223 and configured to filter the air supplied from the clean sub-fab 213. The at least one clean fab filter 222 is connected to the clean room pipeline 223. The clean fab filter 222 is disposed in the clean fab 212, and configured to filter the air from the clean sub-fab 113 before supplying the filtered air to the clean fab 212. The main filter 221 and the clean fab filter 222 may be high efficiency particulate air (HEPA) filters. The HEPA filters can remove at least 99.95% of particles having a diameter greater than or equal to 0.3 micrometers from the air that passes therethrough. The HEPA filters may each include a mat of randomly arranged fibers. The fibers are typically composed of fiberglass and have diameters between 0.5 and 2.0 micrometers. The floor 211 of the clean room system 200 includes at least one vent area 211a for air communication between the clean fab 212 and the clean sub-fab 213. Specifically, the air flows from the clean fab 212 to the clean sub-fab 213 through the vent area 211a. The vent area 211a has a plurality of vent holes for allowing air-communication between the clean fab 212 and the clean sub-fab 213. Therefore, the air in the clean sub-fab 213 is pumped into the clean room pipeline 223, filtered by the main filter 221, filtered by the clean fab filter 222, and supplied to the clean fab 212. The air in the clean fab 212 blows the particles away from the clean fab 212 and flows into the clean sub-fab 213 through the vent holes in the vent area 211a. Accordingly, the air is continuously filtered and circulated in the clean fab 212 and the clean sub-fab 213 of the clean room system 200. For the wafer processing apparatus (e.g., the exposure apparatus 300) disposed in the clean fab 212, the ACC module 240 supplies clean air to an inlet port of the wafer processing apparatus (e.g., an inlet port 301 of the exposure apparatus 300). The ACC module 240 draws air from the clean sub-fab 213, filters the particle in the air, and adjusts temperature and humidity of the filtered air to meet the air quality requirement of the wafer processing apparatus. As shown in FIG. 2, the air supplied from the ACC module 240 blows the particles away from the exposure apparatus 300, and then flows into the clean fab 212 through a vent port 302 of the exposure apparatus 300. Accordingly, the particle concentration in the exposure apparatus 300 can be maintained at a low level.

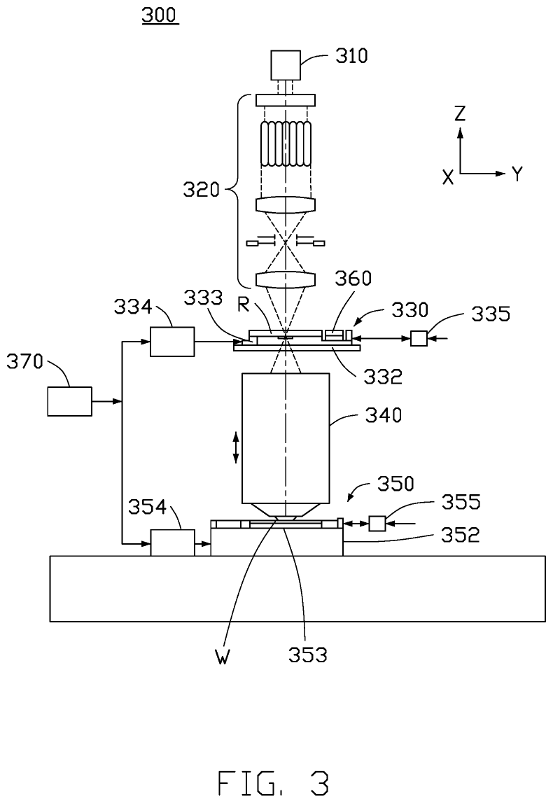

Referring to FIG. 3, a schematic diagram of the exposure apparatus 300 is illustrated. The exposure apparatus 300 is a lithography apparatus for transferring a pattern of a reticle R onto a semiconductor wafer W. The exposure apparatus 300 includes an illumination module 320 for illuminating a reticle R by using light provided from a light source 310, a reticle stage 330 for positioning the reticle R, and a projection module 340 for projecting the pattern of the reticle R onto the wafer W. The exposure apparatus 300 also includes a wafer stage 350 for positioning the wafer W, a determination unit 360, and a control unit 370 (e.g., a processor).

The reticle stage 330 positions the reticle R by moving the reticle R in the Y-axis direction. In this implementation, the reticle stage 330 for holding the reticle R includes a reticle stage base 332, and a reticle holder 333 disposed on the reticle stage base 332 and for holding the reticle R over the reticle stage base 332. A first driving unit 334 drives the reticle stage base 332 according to a driving pattern. A first interferometer 335 continuously measures the position of the reticle stage base 332. The control unit 370 controls the first driving unit 334 to move the reticle stage base 332 according to the driving pattern at high accuracy.

The determination unit 360 determines a feature of the reticle R placed on the reticle stage base 332. The determination unit 360 is constructed by, for example, a reading unit that reads an identifier such as a barcode formed on the reticle R. Also, the determination unit 360 may be constructed by an image sensing unit, such as an area sensor, reflective sensor, or camera, which senses the image of the reticle R and by an image processing unit that processes an image sensed by the image sensing unit. The feature of the reticle R includes, for example, at least one of the type of the reticle or the shape of the reticle. The type of the reticle may vary. Examples are a general reticle (e.g., a reticle on which a circuit pattern is drawn) used to fabricate a semiconductor device, and a special reticle used for a special purpose. The special reticle may include various jigs and is not limited to the reticle on which a circuit pattern is formed.

The projection module 340 projects the pattern of the reticle R illuminated by the light from the illumination module 320 at a predetermined magnification ratio (e.g., 1/4 or 1/5) onto the wafer W. The projection module 340 may employ a first optical module solely including a plurality of lens elements, a second optical module including a plurality of lens elements and at least one concave mirror (e.g., a catadioptric optical system), a third optical module including a plurality of lens elements and at least one diffractive optical element such as a kinoform, and a full mirror module. Any necessary correction of chromatic aberration may be performed by using a plurality of lens elements made from soda-lime glass materials having different dispersion values (or Abbe values), or arranging a diffractive optical element to disperses the light in a direction opposite to that of the lens elements.

The wafer stage 350 positions the wafer W by moving the wafer W in the X- and Y-directions. In this implementation, the wafer stage 350 includes a wafer stage base 352 on which the wafer W is placed, a wafer holder 353 for holding the wafer W on the wafer stage base 352, and a second driving unit 354 for driving the wafer stage base 352. A second interferometer 355 continuously measures the position of the wafer stage base 352. The control unit 370 controls the position of the wafer stage base 352 through the second driving unit 354 at high accuracy.

The control unit 370 includes a central processing unit (CPU) and a memory, and controls the overall operation of the exposure apparatus 300. The control unit 370 controls an exposure process of transferring the pattern of the reticle R onto the wafer W.

During the exposure process, particle contamination to the exposure apparatus 300 (particularly the projection module 340) may cause the photolithographic pattern transmitted on the wafer W to change, distort, or alter from its intended design, ultimately impacting the quality of the semiconductor device manufactured. Therefore, it is critical to maintain the particle concentration in the projection module 340 of the exposure apparatus 300 at a low level. The ACC module 240 is configured to continuously supply clean air to the projection module 340, and blow away particles in the projection module 340 of the exposure apparatus 300.

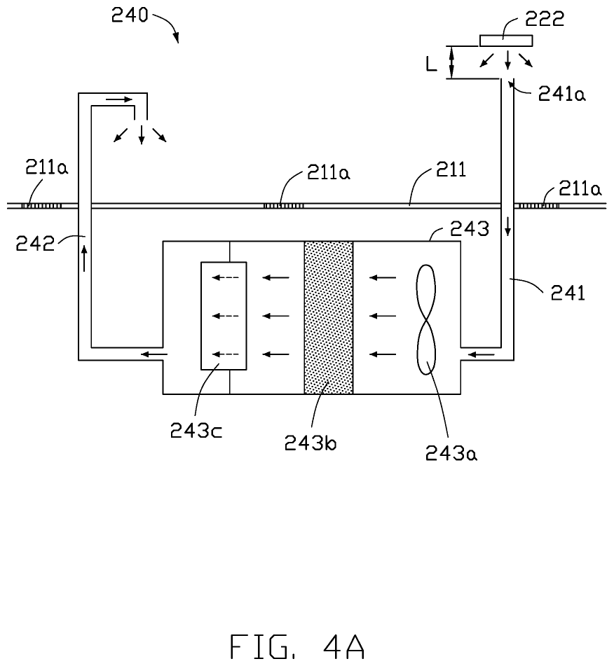

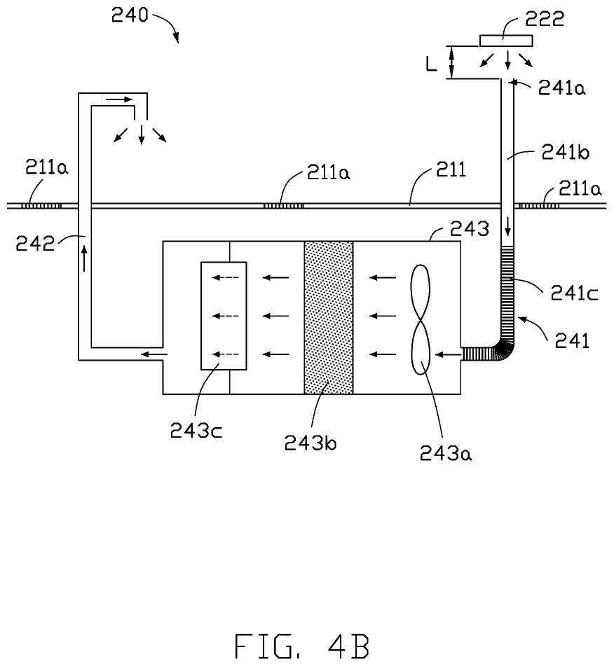

Referring to FIGS. 4A and 4B, schematic diagrams of the ACC module 240 of the clean room system 200 are illustrated. As shown in FIGS. 4A and 4B, the ACC module 240 includes an ACC inlet tube 241, a main cabinet 243, and an ACC pipeline 242. The ACC inlet tube 241 is configured to supply air from the clean fab 212 of the clean room system 200 to the ACC module 240. The ACC inlet tube 241 has two ends. One end of the ACC inlet tube 241 is connected to the main cabinet 243. The other end of the ACC inlet tube 241 has an open end. The open end of the ACC inlet tube 241 is disposed under the clean fab filter 222. A distance L between the open end of the ACC inlet tube 241 and the clean fab filter 222 is within a range of 300 mm to 600 mm. The air drawn into the ACC inlet tube 241 is already filtered by the main filter 221 and the clean fab filter 222, and has a lower particle concentration than the air in the clean sub-fab 213. The main cabinet 243 of the ACC module 240 is connected to the ACC inlet tube 241 and configured to generate clean air from the air supplied from the ACC inlet tube 241. The main cabinet 243 of the ACC module 240 includes a fan 243a, a chemical filter 243b, and a moisture control unit 243c. The fan 243a of the main cabinet 243 is configured to draw the air from the clean fab 212 of the clean room system 200 into the ACC inlet tube 241. In other words, by operating the fan 243a of the main cabinet 243, the air filtered by the clean fab filter 222 flows into the ACC inlet tube 241 via the open end 241a of the ACC inlet tube 241. The chemical filter 243b is configured to remove chemical materials and/or particles in the air supplied from the ACC inlet tube 241. The moisture control unit 243c is configured to control a moisture and a temperature of the air supplied from the ACC inlet tube 241. The ACC pipeline 242 is connected to the main cabinet 243 and configured to supply the clean air generated by the main cabinet 243 to the wafer processing apparatus (e.g., the exposure apparatus 300) in the clean fab 212 of the clean room system 200. The ACC pipeline 242 has two ends. One end of the ACC pipeline 242 is connected to the main cabinet 243. The other end of the ACC pipeline 242 is connected to the inlet port 301 of the exposure apparatus 300 (e.g., shown in FIG. 2). The air supplied from the ACC pipeline 242 of the ACC module 240 blows the particles away from the exposure apparatus 300, and then flows into the clean fab 212 through the vent port 302 of the exposure apparatus 300. Therefore, the ACC module 240 ensures the air quality (e.g., particle and chemical material concentration, moisture, temperature, etc.) in the exposure apparatus 300.

The ACC inlet tube 241 of the ACC module 240 as shown in FIG. 4A may be a single tube made of aluminum. In some implementations, the ACC inlet tube 241 of the ACC module 240 may include a first portion 241b and a second portion 241c connected to the first portion 241b, as shown in FIG. 4B. The first portion 241b of the ACC inlet tube 241 may be made of polyvinyl chloride (PVC), and the second portion 241c of the ACC inlet tube 241 is a flexible hose. The second portion 241c of the ACC inlet tube 241 is connected to the main cabinet. The open end 241a of the ACC inlet tube 241 is disposed at the first portion 241b of the ACC inlet tube 241.

Compared to the ACC module 140 of the clean room system 100 in FIG. 1, the ACC module 240 of the clean room system 200 in FIG. 2 has the ACC inlet tube 241 that can draw air filtered by the clean fab filter 222 in the clean fab 212, while the ACC module 140 of the clean room system 100 in FIG. 1 draws air from the clean sub-fab 113. The air filtered by the clean fab filter in the clean fab has a higher air quality (or a lower particle concentration) than the air in the clean sub-fab. Therefore, the ACC module 240 of the clean room system 200 ensures the cleanliness of the air generated by the main cabinet 243 of the ACC module 240. Also, the service life of the chemical filter 243b in the main cabinet 243 is prolonged by providing air with a low particle concentration into the chemical filter 243b.

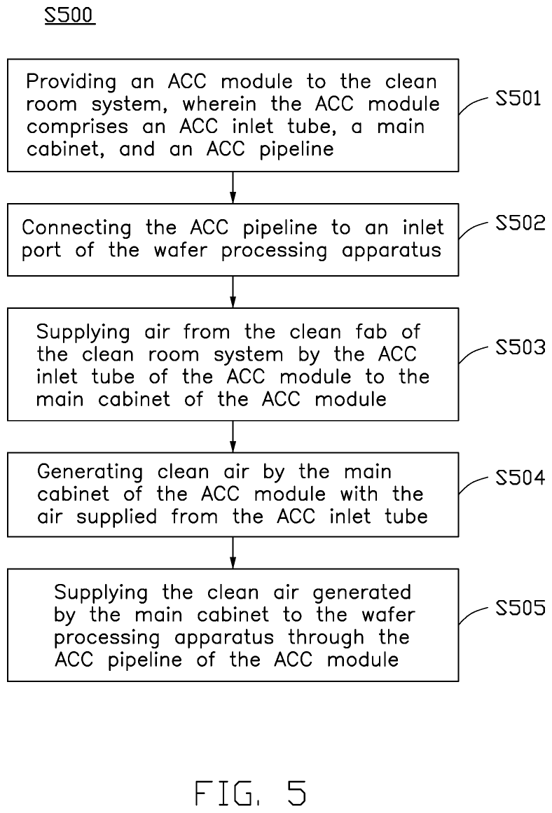

Referring to FIG. 5, a flowchart of a method S500 of improving air quality of a wafer processing apparatus in a clean room system according to an implementation of the present disclosure is provided. As shown in FIG. 5 the method S500 includes actions S501 to S505.

In action S501, an air control cabinet (ACC) module is provided to the clean room system. The clean room system and the ACC module may correspond to the clean room system 200 and the ACC module 240, respectively, as illustrated in FIGS. 2 to 4B. The clean room system 200 has a clean fab 212 and a clean sub-fab 213. The wafer processing apparatus (e.g., the exposure apparatus 300) is disposed in the clean fab of the clean room system 200. Specifically, the clean room system 200 includes the main body 210 having the inner space, the floor 211 disposed in the inner space of the main body 210. The inner space of the main body 210 is divided into the clean fab 212 and the clean sub-fab 213 by the floor 211. The clean fab 212 is configured to be disposed with at least one wafer processing apparatus. The clean sub-fab 213 is configured to be disposed with at least one auxiliary equipments (such as power supply equipments, ventilation control equipments, pumps, and so on). The ACC module 240 includes the ACC inlet tube 241, the main cabinet 243, and the ACC pipeline 242.

In action S502, the ACC pipeline 242 of the ACC module 240 is connected to an inlet port of the wafer processing apparatus (e.g., the inlet port 301 of the exposure apparatus 300). The ACC pipeline 242 has two ends. One end of the ACC pipeline 242 is connected to the main cabinet 243. The other end of the ACC pipeline 242 is connected to the inlet port 301 of the exposure apparatus 300.

In action S503, the ACC inlet tube 241 of the ACC module 240 supplies air form the clean fab 212 of the clean room system 200 to the main cabinet 243 of the ACC module 240. The ACC inlet tube 241 has two ends. One end of the ACC inlet tube 241 is connected to the main cabinet 243. The other end of the ACC inlet tube 241 is an open end. The open end of the ACC inlet tube 241 is disposed in the clean fab 212 of the clean room system 200. The clean room system 200 further includes the clean room pipeline 223, the main filter 221, and at least one clean fab filter 222. The clean room pipeline 223 is coupled to the clean fab 212 and the clean sub-fab 213 and configured to supply air from the clean sub-fab 213 to the clean fab 212. The main filter 221 is coupled to the clean room pipeline 223 and configured to filter the air supplied from the clean sub-fab 213. The at least one clean fab filter 222 is connected to the clean room pipeline 223. The clean fab filter 222 is disposed in the clean fab 212 and configured to filter the air supplied to the clean fab 212. A distance L between the open end of the ACC inlet tube 241 and the clean fab filter 222 may be within a range of 300 mm to 600 mm.

In action S504, the main cabinet 243 of the ACC module 240 generates clean air from the air supplied from the ACC inlet tube 241. The main cabinet 243 of the ACC module 240 includes the fan 243a, the chemical filter 243b, and the moisture control unit 243c. The fan 243a of the main cabinet 243 is configured to draw the air from the clean fab 212 of the clean room system 200 into the ACC inlet tube 241. In other words, by operating the fan 243a of the main cabinet 243, the air filtered by the clean fab filter 222 flows into the ACC inlet tube 241 via the open end 241a of the ACC inlet tube 241. The chemical filter 243b is configured to remove chemical materials and/or particles in the air supplied from the ACC inlet tube 241. The moisture control unit 243c is configured to control the moisture and temperature of the air supplied from the ACC inlet tube 241.

In action S505, the clean air generated by the main cabinet 243 of the ACC module 240 is supplied to the wafer processing apparatus (e.g., the exposure apparatus 300) through the ACC pipeline 242 of the ACC module 240. The air supplied from the ACC pipeline 242 of the ACC module 240 blows particles away from the exposure apparatus 300, and then flows into the clean fab 212 through the vent port 302 of the exposure apparatus 300.

As described above, the ACC module of the implementations of the present disclosure utilizes an ACC inlet tube to draw air from the clean fab of the clean room system The air in the clean fab is filtered by the clean fab filter, and has a higher air quality (or a lower particle concentration) than the air of the clean sub-fab. Therefore, the ACC module of the implementations of the present disclosure ensures the cleanliness of the air supplied into the wafer processing apparatus. Also, the service life of the chemical filter in the ACC module is prolonged by providing air with lower particle concentrations.

The implementations shown and described above are only examples. Many details are often found in the art such as the other features of an air control cabinet module and a clean room system having the same. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the implementations described above may be modified within the scope of the claims.

What is claimed is:

1. An air control cabinet (ACC) module for a clean room system, wherein the clean room system has a clean fab and a clean sub-fab, and the clean fab of the clean room system is configured to be disposed with at least one wafer processing apparatus, the ACC module comprising:
an ACC inlet tube configured to supply air from the clean fab of the clean room system to the ACC module;
a main cabinet connected to the ACC inlet tube and configured to generate clean air from the air supplied from the ACC inlet tube; and
an ACC pipeline connected to the main cabinet and configured to supply the clean air generated by the main cabinet to the wafer processing apparatus in the clean fab of the clean room system.

2. The ACC module of claim 1, wherein the clean room system further comprises at least one clean fab filter disposed in the clean fab, the ACC inlet tube has two ends, one end of the ACC inlet tube is connected to the main cabinet, another end of the ACC inlet tube is an open end, and a distance between the open end of the ACC inlet tube and the clean fab filter is within a range of 300 mm to 600 mm.

3. The ACC module of claim 1, wherein the ACC inlet tube is a single tube made of aluminum.

4. The ACC module of claim 1, wherein the ACC inlet tube comprises a first portion and a second portion connected to the first portion, the first portion of the ACC inlet tube is made of polyvinyl chloride (PVC), and the second portion of the ACC inlet tube is a flexible hose.

5. The ACC module of claim 4, wherein the second portion of the ACC inlet tube is connected to the main cabinet.

6. The ACC module of claim 1, wherein the main cabinet comprises a fan configured to draw the air from the clean fab of the clean room system into the ACC inlet tube.

7. The ACC module of claim 1, wherein the main cabinet comprises a chemical filter configured to remove chemical materials and particles in the air supplied from the ACC inlet tube.

8. The ACC module of claim 1, wherein the main cabinet comprises a moisture control unit configured to control a moisture and a temperature of the air supplied from the ACC inlet tube.

9. The ACC module of claim 1, wherein the wafer processing apparatus is an exposure apparatus for transferring a pattern onto a semiconductor wafer.

10. A clean room system for processing semiconductor wafers, the clean room system comprising:
a main body having an inner space;
a floor disposed in the inner space of the main body, wherein the inner space of the main body is divided into a clean fab and a clean sub-fab by the floor, and the clean fab is configured to be disposed with at least one wafer processing apparatus; and
an air control cabinet (ACC) module configured to supply clean air to the clean fab, the ACC comprising:
an ACC inlet tube configured to supply air from the clean fab of the clean room system to the ACC module;
a main cabinet disposed at the clean sub-fab, wherein the main cabinet is connected to the ACC inlet tube and configured to generate clean air from the air supplied from the ACC inlet tube; and
an ACC pipeline connected to the main cabinet and configured to supply the clean air generated by the main cabinet to the wafer processing apparatus in the clean fab.

11. The clean room system of claim 10, wherein the floor comprises at least one vent area for air communication between the clean fab and the clean sub-fab.

12. The clean room system of claim 10, further comprising a clean room pipeline coupled to the clean fab and the clean sub-fab and configured to supply air from the clean sub-fab to the clean fab.

13. The clean room system of claim 12, further comprising a main filter coupled to the clean room pipeline and configured to filter air supplied from the clean sub-fab.

14. The clean room system of claim 12, further comprising at least one clean fab filter connected to the clean room pipeline, wherein the clean fab filter is disposed in the clean fab and configured to filter air supplied to the clean fab.

15. The clean room system of claim 14, wherein the ACC inlet tube of the ACC module has two ends, one end of the ACC inlet tube is connected to the main cabinet, another end of the ACC inlet tube is an open end, and a distance between the open end of the ACC inlet tube and the clean fab filter is within a range of 300 mm to 600 mm.

16. The clean room system of claim 10, wherein the wafer processing apparatus is an exposure apparatus for transferring a pattern onto the semiconductor wafers, the exposure apparatus comprises a projection module having a plurality of lens, and the ACC pipeline is configured to supply the clean air to the projection module of the exposure apparatus.

17. A method of improving air quality of a wafer processing apparatus in a clean room system, wherein the clean room system has a clean fab and a clean sub-fab, and the wafer processing apparatus is disposed in the clean fab of the clean room system, the method comprising:
providing an air control cabinet (ACC) module to the clean room system, wherein the ACC module comprises an ACC inlet tube, a main cabinet, and an ACC pipeline;
connecting the ACC pipeline to an inlet port of the wafer processing apparatus;
supplying air from the clean fab of the clean room system by the ACC inlet tube of the ACC module to the main cabinet of the ACC module;
generating clean air by the main cabinet of the ACC module from the air supplied from the ACC inlet tube; and
supplying the clean air generated by the main cabinet to the wafer processing apparatus through the ACC pipeline of the ACC module.

18. The method of claim 17, wherein the clean room system further comprises at least one clean fab filter disposed in the clean fab, the ACC inlet tube has two ends, one end of the ACC inlet tube is connected to the main cabinet, another end of the ACC inlet tube is an open end, and a distance between the open end of the ACC inlet tube and the clean fab filter is within a range of 300 mm to 600 mm.

19. The method of claim 17, wherein the wafer processing apparatus is an exposure apparatus for transferring a pattern onto a semiconductor wafer.

20. The method of claim 17, wherein the main cabinet of the ACC module comprises a fan, a chemical filter, and a moisture control unit, the fan is configured to draw the air from the clean fab of the clean room system into the ACC inlet tube, the chemical filter is configured to remove chemical materials and particles in the air supplied from the ACC inlet tube, and the moisture control unit is configured to control a moisture and a temperature of the air supplied from the ACC inlet tube.
